(19) United States
(12) Patent Application Publication
(10) Pub. No.: US 2019/0203351 A1
(43) Pub. Date: Jul. 4, 2019

(54) METHOD OF SURFACE TREATMENT

(71) Applicant: FLOSFIA INC., Kyoto (JP)

(72) Inventors: Shigetaka KATORI, Okayama (JP); Takashi SHINOHE, Kyoto (JP); Takuto IGAWA, Kyoto (JP)

(21) Appl. No.: 16/234,968

(22) Filed: Dec. 28, 2018

(30) Foreign Application Priority Data
Dec. 29, 2017 (JP) 2017-255172

(51) Int. Cl. C23C 16/448

(52) U.S. Cl. CPC C23C 16/4486

(57) ABSTRACT

In a first aspect of a present inventive subject matter, a method of surface treatment includes preparing a raw material solution containing a chemical substance and a solvent with a boiling point; homogenizing the raw material solution containing the chemical substance and the solvent; generating atomized droplets by atomizing the raw material solution containing the chemical substance and the solvent; supplying carrier gas to the atomized droplets to carry the atomized droplets onto a base; and causing thermal reaction of the atomized droplets adjacent to the base at a temperature that is the boiling point of the solvent or at a higher temperature than the boiling point of the solvent contained in the raw material solution to apply surface treatment to the base.

### CROSS-REFERENCE TO RELATED APPLICATION

This application is a new U.S. patent application that claims priority benefit of Japanese patent application No. 2017-255172 filed on Dec. 29, 2017, the disclosures of which are incorporated herein by reference in its entirety.

### BACKGROUND OF THE INVENTION

### Field of the Invention

The present disclosure relates to a method of surface treatment. Also, the present disclosure relates to a method of forming a film on a base.

### Description of the Related Art

A method of forming polymer and an organic film from a raw material solution containing an organic compound such as a monomer are open to the public (For reference, see US 2016/0215391).

Also, a mist etching apparatus and a mist etching method are open to the public (For reference, see Japanese Unexamined Patent Application Publication No. JP2011-181784A). The mist etching apparatus includes a mist generating unit to atomize an etching solution, and an etching unit, in which an etching target is arranged to be etched. The mist generating unit includes a mist generating device, a container that contains the etching solution to be atomized into the mist, and an exit of the mist to be sent outside the mist generating unit. The etching unit includes an entrance through that the mist is introduced, and the etching target is arranged in the etching unit. At the etching unit, the mist is vaporized.

However, when a raw material solution containing an organic compound is atomized and/or when a raw material solution is atomized by use of ultrasonic vibration, velocity of the raw material solution tends to change while the raw material solution is atomized, and that results in stagnation of generating atomized droplets from the raw material solution.

### SUMMARY OF THE INVENTION

In a first aspect of a present inventive subject matter, a method of surface treatment includes preparing a raw material solution containing a chemical substance and a solvent with a boiling point; homogenizing the raw material solution containing the chemical substance and the solvent; generating atomized droplets by atomizing the raw material solution containing the chemical substance and the solvent; supplying carrier gas to the atomized droplets to carry the atomized droplets onto a base; and causing thermal reaction of the atomized droplets adjacent to the base at a temperature that is the boiling point of the solvent or at a higher temperature than the boiling point of the solvent contained in the raw material solution to apply surface treatment to the base.

In a second aspect of a present inventive subject matter, a method of surface treatment includes preparing a raw material solution by mixing a chemical substance in a solvent with a boiling point; homogenizing the raw material solution containing the chemical substance and the solvent during mixing the chemical substance in the solvent and/or after the raw material solution is prepared; generating atomized droplets by atomizing the raw material solution containing the chemical substance and the solvent; supplying carrier gas to the atomized droplets to carry the atomized droplets onto a base; and causing thermal reaction of the atomized droplets adjacent to the base at a temperature that is the boiling point of the solvent or at a higher temperature than the boiling point of the solvent contained in the raw material solution to apply surface treatment to the base.

According to an embodiment of a present inventive subject matter, the chemical substance contained in the raw material solution is a raw material for the surface treatment of the base.

Also, according to an embodiment of a present inventive subject matter, the chemical substance comprised in the raw material solution comprises a low molecular compound.

Furthermore, according to an embodiment of a present inventive subject matter, it is suggested that the solvent comprised in the raw material solution comprises an organic solvent.

It is suggested that the solvent contained in the raw material solution contains an aprotic solvent.

Furthermore, it is suggested that the homogenizing the raw material solution containing the chemical substance and the solvent is done by use of an ultrasonic homogenizer.

According to an embodiment of a present inventive subject matter, it is suggested that the generating atomized droplets by atomizing the raw material solution is done using ultrasonic vibration.

Also, according to an embodiment of a present inventive subject matter, it is suggested that the carrier gas is supplied to the atomized droplets at a flow rate that is in a range of 0.1 L/min to 10 L/min.

Furthermore, it is suggested that the carrier gas is supplied to the atomized droplets at a flow rate that is in a range of 0.1 L/min to 10 L/min.

Also, it is suggested that the causing the thermal reaction of the atomized droplets adjacent to the base may be done at the temperature in a range of 120° C. to 350° C.

According to an embodiment of the method of a present inventive subject matter, it is suggested that the homogenizing the raw material solution containing the chemical substance and the solvent may be repeated twice or more during mixing the chemical substance in the solvent and/or after the raw material solution is prepared.

### BRIEF DESCRIPTION OF THE DRAWING

FIG. 1 shows a schematic diagram of a mist chemical vapor deposition (CVD) apparatus that may be used as a film (layer)-formation apparatus according to an embodiment of a method of a present inventive subject matter.

FIG. 2 shows a schematic diagram of an ultrasonic homogenizer according to an embodiment of a present inventive subject matter.

FIG. 3 shows a schematic cross-sectional part of a homogenous valve that is a part of a high-pressure homogenizer.

FIG. 4 shows a UV-visible absorption measurement result of an organic film obtained according to an embodiment of a method of a present inventive subject matter.

### DETAILED DESCRIPTION OF EMBODIMENTS

The terminology used herein is for the purpose of describing particular embodiments only and is not intended to be limiting of the subject matter. As used herein, the singular forms “a”, “an” and “the” are intended to include the plural forms as well, unless the context clearly indicates otherwise.

As used herein, the term “and/or” includes any and all combinations of one or more of the associated listed items.

According to a present inventive subject matter, a method of surface treatment includes preparing a raw material solution containing a chemical substance and a solvent with a boiling point; and homogenizing the raw material solution containing the chemical substance and the solvent. The method further includes generating atomized droplets by atomizing the raw material solution that contains the chemical substance and the solvent. Also, the method further includes supplying carrier gas to the atomized droplets to carry the atomized droplets onto a base; and causing thermal reaction of the atomized droplets adjacent to the base at a temperature that is the boiling point of the solvent or at a higher temperature than the boiling point of the solvent contained in the raw material solution to apply surface treatment to the base.

(Preparing a Mixed Solution)

According to an embodiment of a method of surface treatment of a present inventive subject matter, a mixed solution is obtained by mixing a chemical substance and a solvent. The mixed solution is not particularly limited as long as the chemical substance is dissolved and/or dispersed in the solvent. Also, a method of mixing the chemical substance and the solvent is not particularly limited and a known mixing method of such a chemical substance and a solvent may be used. According to a present inventive subject matter, the mixed solution has a viscosity that is preferably 100 cP or less.

The chemical substance is not particularly limited as long as the chemical substance is applicable to surface treatment, and a known chemical substance may be used. The chemical substance may be fluid. Also, the chemical substance may be solid. Furthermore, the chemical substance may be gas. Also, the chemical substance may be a sol or a gel. Examples of the chemical substance include an etching agent, a surface modifier, a cleaning agent, a rinse agent, and a raw material to form a film. According to an embodiment of a method of a present inventive subject matter, the chemical substance is preferably a raw material to form a film. The mixing ratio of the raw material in the raw material solution is not particularly limited, however, preferably in a range of 0.0001 weight % (wt %) to 80 wt %, and further preferably in a range of 0.001 wt % to 50 wt %.

The etching agent is not particularly limited as long as an object of a present inventive subject matter is not interfered with, and a known etching agent may be used. A known acid may be used as the etching agent. Examples of the acid include hydrofluoric acid, hydrochloric acid, sulfuric acid, phosphoric acid, nitric acid, acetic acid, carbonate acid, formic acid, benzoic acid, zinc acid, hypochlorous acid, sulfite, next sulfite, nitrous acid, hyponitrous acid, phosphorous acid, proton acid such as hypophosphorous acid, and a mixture of two or more thereof. Also, a known alkali may be used as the etching agent. Examples of the alkali include sodium hydroxide, potassium hydroxide, calcium hydroxide, and a mixture of two or more thereof. Also, the etching agent that is used to etch metals such as gold, silver, copper, palladium, and platinum may be used and examples of the etching agent include ferric chloride-based etching agent, cyanate/oxygen-based etching agent, ferrocyanic acid salt/ferricyanic acid salt-based etching agent, thiocarbamide-based etching agent, potassium iodide/iodine-based etching agent (KI/I2; triiodide) and a combination of two or more thereof. The raw material solution may contain one of the examples of the etching agent mentioned above. Also, the raw material solution may contain two or more of the examples of the etching agent mentioned above.

The surface modifier is not particularly limited as long as an object of a present inventive subject matter is not interfered with, and a known surface modifier may be used. Examples of the surface modifier include anionic surfactant, cationic surfactant, nonionic surfactant, amphoteric surfactant, polymeric surfactant, dispersing agent, alcohols, fatty acid, amines, amides, imides, metallic soap, fatty acid oligomer compound, silane coupling agent, titanate coupling agent, aluminate coupling agent, phosphoric coupling agent, carboxylic acid coupling agent, fluorine-based surfactant, and boron-based surfactant. The raw material solution may contain one of the examples of the surface modifier mentioned above. Also, the raw material solution may contain two or more of the examples of the surface modifier mentioned above.

The cleaning agent is not particularly limited as long as an object of a present inventive subject matter is not interfered with, and a known cleaning agent may be used. Examples of the cleaning agent include a surfactant such as anion surfactant and nonionic surfactant, and a metal soap.

The rinse agent is not particularly limited as long as an object of a present inventive subject matter is not interfered with, and a known rinse may be used. Examples of the rinse include hydrofluorocarbon (HFC), and hydro fluoro ether (HFE).

The raw material to form a film may be a known raw material to form a film. The raw material may be an inorganic material. Also, the raw material may be an organic material. Examples of the raw material to form a film include a metal, a metal compound, and an organic compound. Examples of the metal may be one or more metals selected from among gallium, iron, indium, aluminum, vanadium, titanium, chromium, rhodium, nickel, cobalt, zinc, magnesium, calcium, yttrium, strontium, barium, and silicon. Also, examples of the metal compound include an oxide of one or more metals mentioned above, a nitride of one or more metals mentioned above, a carbide of one or more metals mentioned above, a halide such as a chloride, a bromide or an iodide of one or more metals mentioned above, a metal salt such as a nitrate, a sulfate, a perchlorate, an acetate, a phosphoric salt, or a bromate salt, and a metal complex such as acetylacetonato complex, ammine complex, ethylenediamine complex of one or more metals mentioned above. The organic compound is not particularly limited, and a known organic compound may be used. The organic compound may be a low molecular compound. Also, the organic compound may be a macromolecular organic compound. The term “low-molecular compound” herein means a chemical compound with a molecular weight that is less than 10000. Also, the term “macromolecular” herein means a chemical compound with a molecular weight that is 10000 or more.

According to an embodiment of a present inventive subject matter, the raw material to form a film is preferably an organic compound, which is suitable to obtain atomized droplets from a raw material solution containing the organic compound, and further preferably low-molecular organic compound. The low-molecular organic compound is not particularly limited and may be a known low-molecular organic compound, however, according to an embodiment of a present inventive subject matter, the raw material to form a film is preferably an aromatic compound or an organic metal complex. According to an embodiment of a present inventive subject matter, the raw material to form a film is further preferably an organic metal complex of a low-molecular organic compound.

Examples of the aromatic compound include naphthalene, anthracene, tetracene, rubrene, pentacene, benzopentacene, dibenzopentacene, tetrabenzopentacene, naphthopentacene, hexacene, heptacene, nanoacene, fluorene, fluoranthene, phenanthrene, chrysene, triphenylene, tetraphene, picene, flumilene, tetraphene, pyrene, anthanthrene, propylene, coronene, benzocoronene, dibenzocoronene, hexabenzocoronene, benzo dicoronene, perylene, terrylene, diperylene, quaterrylene, trinaphthylene, heptaphene, ovalene, rubicene, violanthrone, isoviolanthrone, circumanthracene, bisanthene, zethrene, heptazethrene, pyrans, kekulene, truxene, fullerene and derivatives thereof.

The organic metal complex is not particularly limited as long as an object of a present inventive subject matter is not interfered with, and a known organic metal complex may be used. The organic metal complex includes a central metal. Examples of the central metal include iron (Fe), copper (Cu), zinc (Zn), cobalt (Co), aluminum (Al), nickel (Ni), scandium (Sc), yttrium (Y), titanium (Ti), zirconium (Zr), hafnium (Hf), vanadium (V), niob (Nb), tantalum (Ta), chromium (Cr), molybdenum (Mo), tungsten (W), manganese (Mn), technetium (Tc), rhenium (Re), ruthenium (Ru), osmium (Os), rhodium (Rh), iridium (Ir), palladium (Pd), platinum (Pt), silver (Ag), gold (Au), cadmium (Cd), and mercury (Hg). According to embodiments of a method of a present inventive subject matter, the central metal of the organic metal complex is preferably aluminum (Al) or copper (Cu). Also, according to embodiments of a method of a present inventive subject matter, the central metal of the organic metal complex is further preferably copper (Cu).

Examples as a ligand of the organic metal complex include quinolinol, benzoquinolinol, acridinyl, phenanthryldinyl, hydroxyphenylthiazole, hydroxydiaryl oxadiazole, hydroxydiaryl thiadiazole, hydroxyphenyl pyridine, hydroxyphenyl benzimidazole, hydroxybenzotriazole, hydroxyflavone, bipyridyl, phenanthroline, phthalocyanine, porphyrin, cyclopentadiene. β-diketone, and azo methine. According to a present inventive subject matter, the ligand of the organic metal complex is preferably phthalocyanine.

The solvent is not particularly limited, as long as an object of a present inventive subject matter is not interfered with, and a known solvent may be used. The solvent may be an inorganic solvent such as water. Also, the solvent may be an organic solvent. According to embodiments of a method of a present inventive subject matter, it is preferable that the solvent contains an organic solvent to obtain a raw material solution suitable to generate atomized droplets, and the solvent is further preferably an organic solvent.

The organic solvent is not particularly limited as long as the organic solvent is used as a solvent and an object of a present inventive subject matter is not interfered with. According to an embodiment of a method of a present inventive subject matter, the organic solvent preferably contains a solvent except for protonic polar solvents. Accordingly, the organic solvent may be an aprotic solvent. Also, the organic solvent may be a nonpolar solvent. According to an embodiment of a method of a present inventive subject matter, the organic solvent is further preferably an aprotic solvent. Examples of the aprotic solvent include a carbonate-based solvent, an ether-based solvent, an ester-based solvent, an amide-based solvent, a nitro-based solvent, a sulfur-based solvent, and a nitrile-based solvent. Examples of the carbonate-based solvent include ethylene carbonate, propylene carbonate, butylene carbonate, dimethyl carbonate, ethyl methyl carbonate, and diethyl carbonate. Examples of the ether-based solvent include dimethoxymethane, 1,2-Dimethoxyethane, tetrahydrofuran, 2-Methyltetrahydrofuran, 1,3-Dioxane, 4-Methyl-1,3-dioxolane, cyclopentyl methyl ether, methyl-t-butyl ether, diethylene glycol dimethyl ether, diethylene glycol diethyl ether, and triethylene glycol dimethyl ether. Examples of the ester-based solvent include methyl formate, methyl acetate, ethyl acetate, isopropyl acetate, butyl acetate methyl propionate, γ-butyrolactone and γ-valerolactone. Examples of the amide-based solvent include N,N-dimethyl imidazolidinone, N-methylformamide, N,N-dimethylformamide, N,N-diethylformamide, acetamide, N-methylacetamide, N,N-dimethylacetamide, N-methylpropionamide, and N-methylpyrrolidone. Examples of the nitro-based solvent include nitromethane, and nitrobenzene. Examples of the sulfur-based solvent include sulfolane, 3-Methylsulfolane, and dimethylsulfoxide. Examples of the nitrile-based solvent include acetonitrile, propionitrile, isobutyronitrile, butyronitrile, valeronitrile, and benzonitrile. Examples of the nonpolar solvent include a hydrocarbon-based solvent. According to an embodiment of a method of a present inventive subject matter, the organic solvent may be preferably an aromatic hydrocarbon solvent such as tetralin or 1-methyl naphthalene. Also, according to embodiments of a method of a present inventive subject matter, the organic solvent is preferably the ester-based solvent, and the organic solvent is further preferably butyl acetate.

Also, the raw material solution may further contain an additive. The additive is not particularly limited as long as an object of a present inventive subject matter is not interfered with. The additive may be an acid, an alkali and a solvent. Also, a known additive may be used. The additive may be an inorganic material. Also, the additive may be an organic material. Examples of the acid include hydrofluoric acid, hydrochloric acid, sulfuric acid, phosphoric acid, nitric acid, acetic acid, carbonate acid, formic acid, benzoic acid, zinc acid, hypochlorous acid, sulfite, next sulfite, nitrous acid hyponitrous acid, phosphorous acid, proton acid such as hypophosphorous acid, and a mixture of two or more thereof. Also, examples of the alkali include sodium hydroxide, potassium hydroxide, calcium hydroxide, and a mixture of two or more thereof.

According to an embodiment of a method of a present inventive subject matter, the method includes preparing a raw material solution that contains a chemical substance and a solvent with a boiling point. The mixed solution in that the chemical substance and the solvent are mixed may be used as the raw material solution. The raw material solution may further include an additive. Also, according to the embodiment of the method of the present inventive subject matter, the raw material solution containing the chemical substance and the solvent may be homogenized, that is effective to generate atomized droplets from the raw material solution without stagnation.

Homogenizing the raw material solution containing the chemical substance and the solvent should be done before atomizing the raw material solution containing the chemical substance and the solvent, however, the homogenizing the raw material solution may be done while the chemical substance is mixed into the solvent or the homogenizing the raw material solution may be done after the chemical substance is mixed in the solvent. Also, the homogenizing the raw material solution may be repeated twice or more during mixing the chemical substance in the solvent and/or after the raw material solution is prepared. According to an embodiment of a method of the present inventive subject matter, the method of surface treatment includes preparing a raw material solution by mixing a chemical substance in a solvent with a boiling point; homogenizing the raw material solution containing the chemical substance and the solvent during mixing the chemical substance in the solvent and/or after the raw material solution is prepared; generating atomized droplets by atomizing the raw material solution containing the chemical substance and the solvent; supplying carrier gas to the atomized droplets to carry the atomized droplets onto a base; and causing thermal reaction of the atomized droplets adjacent to the base at a temperature that is the boiling point of the solvent or at a higher temperature than the boiling point of the solvent contained in the raw material solution to apply surface treatment to the base.

The homogenizing the raw material solution may be done by use of a known homogenizer. A high-pressure homogenizer may be used to homogenize the raw material solution. According to an embodiment of a method of a present inventive subject matter, homogenizing the raw material solution by use of an ultrasonic homogenizer is preferable for stable atomization of the raw material solution. The ultrasonic homogenizer is not particularly limited as long as the ultrasonic homogenizer uses ultrasonic vibration, and a known ultrasonic homogenizer may be used. FIG. 2 shows a schematic view of an ultrasonic homogenizer 21 as an example. The homogenizer 21 includes an ultrasonic transducer 22, an ultrasonic oscillator 23, and an ultrasonic horn 24 connected to the ultrasonic transducer 22. The ultrasonic horn 24 is used to augment the oscillation displacement amplitude provided by the ultrasonic transducer 22. The ultrasonic transducer 22 is configured to be driven by electronic signals sent from the ultrasonic oscillator 23 and to transmit oscillation displacement amplitude to the ultrasonic horn 24, which is in contact with the raw-material solution to homogenize the raw-material solution. The ultrasonic horn 24 may be at least partly arranged in the raw-material solution. The time of homogenizing the raw material solution is not particularly limited, however, preferably in a range of one minute to 24 hours. According to an embodiment of the method of a present inventive subject matter, the time of homogenizing the raw material solution is further preferably in a range of 30 minutes to 12 hours. Also, the frequency of the ultrasonic vibration by the ultrasonic homogenizer is preferably 500 kHz or less to obtain the raw material solution suitably homogenized for generating atomized droplets. According to embodiments of a present inventive subject matter, the frequency of the ultrasonic vibration by the ultrasonic homogenizer is further preferably 100 kHz or less, and most preferably 50 kHz or less.

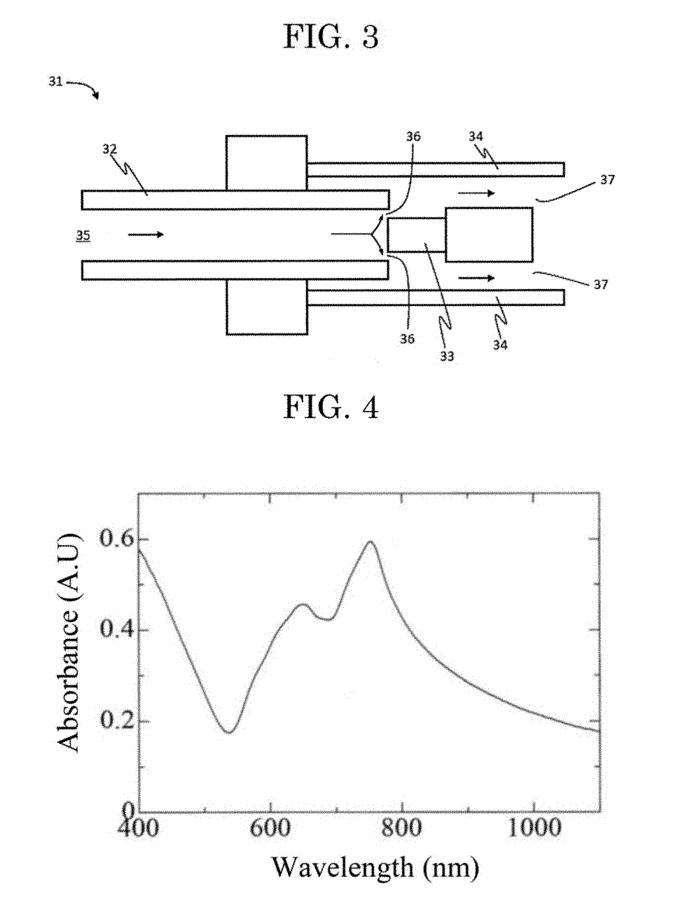

Also, as the high-pressure homogenizer, a homogenizer including a homo valve as shown in FIG. 3 and a pressurization device. FIG. 3 shows a schematic cross-sectional part of a homogenous valve that is a part of the high-pressure homogenizer. The homo valve 31 includes a homo valve seat 32 with a shape of tube, and a homo valve rod 33 in the shape of cylinder. Also, the homo valve 31 includes a breaker ring 34 positioned outside the homo valve seat 32 and the homo valve rod 33. The homo valve rod 33 having an outer diameter smaller than the outer diameter of the homo valve seat 32 is arranged with a gap 36 from an end of the shape of tube of the homo valve seat 32. The arrow shown in FIG. 3 indicates a flow of the raw material solution from an entrance 35 of the homo valve seat 32 to an exit 37 of the homo valve seat 32. The high-pressure homogenizer may include a plunger pump (not shown) as a pressurization device in addition to the homo valve 31. The plunger pump apply pressure to the raw material solution from the side of the entrance 35 of the homo valve seat 32. With this pressure, the raw material solution is passed through the gap 36 and pushed out through the exit 37, and through this flow of the raw material solution being struck on the breaker ring 34, the chemical substance is more dissolved and/or dispersed in the solvent to be a more homogenized raw material solution.

(Generating Atomized Droplets from a Raw Material Solution)

A raw material solution contains a mixed solution obtained by mixing a chemical substance and a solvent mentioned above, and the raw material solution is turned into atomized droplets floating in a space of a container of a generator of atomized droplets. The raw material solution may be turned into atomized droplets by a known method, however, according to an embodiment of a present inventive subject matter, the raw material solution is preferably turned into atomized droplets by use of ultrasonic vibration. Atomized droplets including mist particles, obtained by using ultrasonic vibration and floating in the space have the initial velocity that is zero. Since atomized droplets floating in the space are carriable as gas, the atomized droplets floating in the space are preferable to avoid damage caused by the collision energy without being blown like a spray. The size of droplets is not limited to a particular size, and may be a few mm, however, the size of droplets is preferably 50 μm or less. The size of droplets is further preferably in a range of 100 nm to 10 μm. Also, the frequency of the ultrasonic vibration is not particularly limited, however, according to embodiments of a method of a present inventive subject matter, the ultrasonic vibration preferably includes a frequency that is 0.5 MHz or more for stable atomization. For more enhanced and stable atomization, the frequency of the ultrasonic vibration is preferably 1.0 MHz or more, and further preferably 2.0 MHz or more.

(Carrying the Atomized Droplets onto a Base)

Carrier gas is supplied to atomized droplets floating in the space of a container for generating atomized droplets, and the atomized droplets are carried by the carrier gas onto a base. The carrier gas is not particularly limited as long as an object of the present inventive subject matter is not interfered with, and thus, examples of the carrier gas include an oxidizing gas, an inert gas, and a reducing gas. Examples of the oxidizing gas include oxygen and ozone. Examples of the inert gas include nitrogen and argon. Also, examples of the reducing gas include a hydrogen gas and a forming gas. The type of carrier gas may be one or more, and a dilution gas at a reduced flow rate (e.g., 10-fold dilution gas) may be used further as a second carrier gas. The carrier gas may be supplied from one or more locations. The flow rate of the carrier gas is not particularly limited, however, the flow rate of the carrier gas may be in a range of 0.01 to 20 L/min. According to an embodiment of a present inventive subject matter, the flow rate of the carrier gas may be preferably in a range of 0.1 to 10 L/min. When a dilution gas is used, the flow rate of the dilution gas is preferably in a range of 0.001 to 5 L/min. According to an embodiment of a present inventive subject matter, when a dilution is used, the flow rate of the dilution gas is further preferably in a range of 0.1 to 4 L/min.

(Base)

The base is not particularly limited as long as atomized droplets carried by carrier gas onto the base are able to be thermally reacted to be turned into a film on the base. The material of the base (base material) is not particularly limited as long as an object of a present inventive subject matter is not interfered with, and the base may be a known base. Also, the base may contain an organic compound. Also, the base may contain an inorganic compound. Examples of the base material include inorganic materials, metal materials, and organic materials. Examples of the inorganic materials include quartz, glass, sapphire, titania, silicon carbide, silicon nitride, and aluminum nitride. Also, examples of the metal materials include silicon, aluminum, iron, nickel, copper, and titanium. Examples of the organic materials include a polyester resin such as PET resin, polytrimethylene terephthalate, polybutylene terephthalate, or polyethylene naphthalate, polybutylene naphthalate, acrylic resin, polystyrene resin, polycarbonate resin, polypropylene resin, polyethylene resin, polyvinylchloride resin, and polytetrafluoroethylene. Also, examples of the base material include paper, crystal-structured material, and paper material such as synthetic paper. Examples of the crystal-structured material include a crystalline film such as a perovskite film.

Also, a base including at least a layer formed on the base may be used as a base according to an embodiment of a method of a present inventive subject matter. Two or more layers may be arranged on the base. Examples of the layer that may be formed on the base include a metal layer a semiconductor layer, an electrically-conductive layer, and an electrically-insulating layer. The layer may be partly arranged on the base. Also, the layer may be arranged on an entire surface of the base. Examples of a constituent material of the metal layer may contain one or more metals selected from among gallium, iron, indium, aluminum, vanadium, titanium, chromium, rhodium, nickel, cobalt, zinc, magnesium, calcium, silicon, yttrium, strontium, and barium. Examples of a constituent material of the semiconductor layer include a chemical element such as silicon or germanium, a chemical compound containing one or more chemical elements selected from among chemical elements of Group 3 to Group 5 in the periodic table and chemical elements of Group 13 to Group 15 in the periodic table. Examples of a constituent material of the metal oxide containing one or more chemical elements selected from among chemical elements of Group 3 to Group 5 in the periodic table and chemical elements of Group 13 to Group 15 in the periodic table, a metal sulfide containing one or more chemical elements selected from among chemical elements of Group 3 to Group 5 in the periodic table and chemical elements of Group 13 to Group 15 in the periodic table, a metal selenide containing one or more chemical elements selected from among chemical elements of Group 3 to Group 5 in the periodic table and chemical elements of Group 13 to Group 15 in the periodic table, and a metal nitride containing one or more chemical elements selected from among chemical elements of Group 3 to Group 5 in the periodic table and chemical elements of Group 13 to Group 15 in the periodic table. Examples of a constituent material of the electrically-conductive film include tin-doped indium oxide (ITO), fluorine-doped indium oxide (FTO), zinc oxide (ZnO), aluminum doped zinc oxide (AZO), gallium-doped zinc oxide (GZO), tin oxide (SnO₂), indium oxide (In₂O₃), and tungsten oxide (WO₃). According to an embodiment of the present invention, the electrically-conductive film including an electrically-conductive oxide is preferable, and further preferably is a tin-doped indium oxide (ITO) film. Examples of a constituent material of the electrically-insulating film include aluminum oxide (Al₂O₃), titanium oxide (TiO₂), silicon oxide (SiO₂), silicon nitride (Si₃N₄), and silicon oxynitride (Si₄O₅N₃). Examples of a constituent material of the organic film include the above-mentioned organic materials.

In forming the metal film, the semiconductor film, the electrically-conductive film, and/or the electrically-insulating film, the method of forming the metal film, the semiconductor film, the electrically-conductive film, and/or the electrically-insulating film is not particularly limited, and a known method may be used. Examples of the method of forming the metal film, the semiconductor film, the electrically-conductive film, and/or the electrically-insulating film include a mist CVD method, a sputtering method, a CVD (Chemical Vapor Deposition) method, an SPD (Spray Pyrolysis Deposition) method, an evaporation method, an ALD (Atomic Layer Deposition), and a coating method such as dipping, dropping, a doctor blade coating, ink jet coating, spin coating, brush coating, spray coating, roll coating, air knife coating, curtain coating, wire-bar coating, gravure coating, and inkjet coating.

Variously-shaped bases are available for a base. The base may have a plate shape, a circular plate shape, a shape of fiber, a shape of a stick, a shape of a round pillar, a shape of a square pillar, a shape of a tube, a shape of a spiral, a shape of sphere, and/or a shape of ring. According to an embodiment of a present inventive subject matter, the base may be preferably a substrate. The thickness of the substrate is not particularly limited as long as the substrate is able to support a film to be directly or indirectly formed on the substrate. According to embodiments of a present inventive subject matter, the thickness of the substrate is preferably in a range of 0.5 μm to 100 mm, and further preferably in a range of 1 μm to 10 mm.

(Performing Surface Treatment)

The atomized droplets carried onto the base by the carrier gas are thermally reacted (through “thermal reaction”) at a temperature that is higher than the boiling point of the solvent contained in the raw material solution. Herein, “thermal reaction” works as long as the atomized droplets react by heat, and conditions of reaction are not particularly limited as long as an object of a present inventive subject matter is not interfered with. In embodiments of a present inventive subject matter, the thermal reaction is not particularly limited as long as the thermal reaction is conducted at a temperature that is higher than the boiling point of the solvent, however, the thermal reaction is preferably conducted at a temperature that is 120° C. or higher. Also, the upper limit of the temperature for the thermal reaction is not particularly limited, however, the thermal reaction is preferably conducted at 350° C. or lower, and is further preferably conducted at a temperature that is 250° C. or lower. The temperature of a base on which a film is to be formed can be adjusted by a heater, for example. The base may be arranged on a hot plate.

Also, the thermal reaction may be conducted in any environment such as in a vacuum environment, in a non-oxygen atmosphere, in a reducing-gas atmosphere, or in an oxygen atmosphere, however, the thermal reaction is preferably conducted in a non-oxygen atmosphere or in an oxygen atmosphere. Furthermore, the thermal reaction may be conducted under atmospheric pressure, under increased pressure or under decreased pressure, however, according to embodiments of a present inventive subject matter, the thermal reaction is preferably conducted under atmospheric pressure. Also, according to embodiments of a present inventive subject matter, the surface treatment of the base is forming a film on a surface of the base, and the film thickness is able to be adjusted by changing a film-formation time.

If a film (layer)-formation apparatus with a linear nozzle, through which the atomized droplets are supplied to the base, is used, the film thickness of an organic film to be formed on the base is adjusted by changing the number of passages of the linear nozzle of the film-formation apparatus on or above the base. The linear nozzle of the film-formation apparatus may move over a base to supply the atomized droplets to the base. Also, the linear nozzle of the film-formation apparatus may be fixed at a position and a base is on a conveyor belt to pass the base under the linear nozzle of the film-formation apparatus, for example. Furthermore, two or more linear nozzles of the film-formation apparatus may be arranged at different positions. Also, roll to roll processing techniques may be used to perform surface treatment of the base, according to an embodiment of a present inventive subject matter. Also, two or more bases are arranged to perform surface treatment of the bases.

Even when a chemical substance that tends to be hard to be formed into atomized droplets is mixed in a raw material solution, it is possible to perform surface treatment on a base stably with the method mentioned above.

Embodiments are explained in more details.

### Practical Example 1

1. Film (Layer)-Formation Apparatus

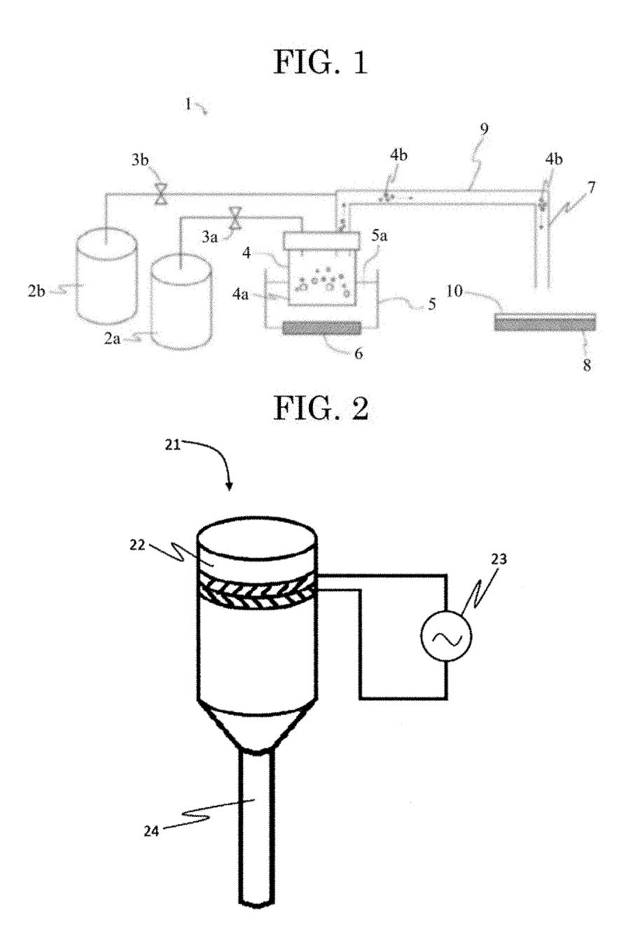

FIG. 1 shows a mist chemical vapor deposition (CVD) apparatus 1 used in practical examples and comparative examples to perform surface treatment of a base 10. The mist CVD apparatus 1 includes a carrier gas supply device 2a, a first flow-control valve 3a to control a flow of a carrier gas that is configured to be sent from the carrier gas supply device 2a, a diluted carrier gas supply device 2b, a second flow-control valve 3b to control a flow of a carrier gas that is configured to be sent from the diluted carrier gas supply device 2b, an atomized droplets (including mist) generator 4 in that a raw material solution 4a is contained, a vessel 5 in that water 5a is contained, and an ultrasonic transducer 6 that may be attached to a bottom surface of the vessel 5. The mist CVD apparatus 1 further includes a hot plate 8 on that the base 10 is placed. The mist CVD apparatus 1 further includes a supply tube 9 at a first end connected to the atomized droplets generator 4 to supply the atomized droplets carried by carrier gas onto the base 10 at a second end of the supply tube 9. The second end of the supply tube 9 may be provided with a nozzle 7 that is positioned adjacent to the base 10 placed on the hot plate 8.

2. Preparation of Raw-Material Solution

A mixed solution was prepared by mixing copper phthalocyanine (molecular weight: 576.08) in butyl acetate, and the mixed solution containing the chemical substance and the solvent was homogenized by use of an ultrasonic homogenizer and prepared as a raw material solution.

3. Film (Layer) Formation Preparation

The raw-material solution 4a obtained at 2. the Preparation of Raw-Material Solution above was set in the container of the atomized droplets generator 4. Also, a glass/ITO substrate (20 mm×25 mm) as a base 10 was placed on the hot plate 8. The hot plate 8 was activated to raise the temperature of the base 10 up to 210° C. The first flow-control valve 3a and the second flow-control valve 3b were opened to supply carrier gas from the carrier gas device 2a and the diluted carrier gas device 2b. The flow rate of the carrier gas from the carrier gas source 2a was set at 4.0 L/min, and the diluted carrier gas from the diluted carrier gas source 2b was set at 4.0 L/min. In this embodiment, nitrogen was used as the carrier gas.

4. Formation of a Film of Copper Phthalocyanine

The ultrasonic transducer 6 was then activated to vibrate at 2.4 MHz, and vibrations were propagated through the water 5a in the vessel 5 to the raw material solution 4a to generate atomized droplets 4b from the raw material solution 4a. The atomized droplets 4b were carried through a supply pipe 9 by the carrier gas onto the base 10, and the atomized droplets 4b heated and thermally reacted adjacent to the base 10 at 210° C. under atmospheric pressure to be formed into a film of copper phthalocyanine on the base 10. The film thickness of the film of copper phthalocyanine that was obtained was approximately 100 nm, and the film-formation time was 40 minutes. During the film formation, the film was stably formed on the substrate due to atomized droplets stably generated from the raw material solution without stagnation. The film of copper phthalocyanine obtained in this embodiment appeared to be blue, and the surface of the base was uniformly colored in blue. Also, a UV-visible absorption measurement was conducted on the film of copper phthalocyanine obtained here at Practical Example 1, and FIG. 4 shows the result. The film of copper phthalocyanine had a first absorption peak in a wavelength range of 600 nm to 700 nm and a second absorption peak in a wavelength range of 700 nm to 800 nm.

It is possible to form a film stably as a surface treatment on a base by the method mentioned above of a present inventive subject matter, even when a chemical substance such as phthalocyanine, which contains a low molecular compound and generally tends to be hard to be formed into atomized droplets, is mixed in a raw material solution.

According to the method of a present inventive subject matter, surface treatment of a base is able to be conducted at a low temperature that is in a range of 120° C. to 350° C., for example. Also, since the method of a present inventive subject matter is able to be conducted under atmospheric pressure without requiring a vacuum system, it is possible to conduct surface treatment including forming a film on a surface of a base stably and easily, and thus, the method of a present inventive subject matter is useful for surface treatment of various objects and devices in various fields. According to the embodiment of the method of a present inventive subject matter, especially when a chemical substance that contains a low molecular compound is used, the method of a present inventive subject matter is effective to conduct surface treatment stably and efficiently.

Furthermore, while certain embodiments of the present inventive subject matter have been illustrated with reference to specific combinations of elements, various other combinations may also be provided without departing from the teachings of the present inventive subject matter. Thus, the present inventive subject matter should not be construed as being limited to the particular exemplary embodiments described herein and illustrated in the Figures, but may also encompass combinations of elements of the various illustrated embodiments.

Many alterations and modifications may be made by those having ordinary skill in the art, given the benefit of the present disclosure, without departing from the spirit and scope of the inventive subject matter. Therefore, it must be understood that the illustrated embodiments have been set forth only for the purposes of example, and that it should not be taken as limiting the inventive subject matter as defined by the following claims. The following claims are, therefore, to be read to include not only the combination of elements which are literally set forth but all equivalent elements for performing substantially the same function in substantially the same way to obtain substantially the same result. The claims are thus to be understood to include what is specifically illustrated and described above, what is conceptually equivalent, and also what incorporates the essential idea of the inventive subject matter.

### REFERENCE NUMBER DESCRIPTION

1 a film (layer)-formation apparatus
2a a carrier gas supply device
2b a diluted carrier gas supply device
3a a flow-control valve of carrier gas
3b a flow-control valve of diluted carrier gas
4 a generator of atomized droplets
4a a raw material solution
4b an atomized droplet
5 a vessel
5a water
6 an ultrasonic transducer
7 a nozzle
8 a hot plate
9 a supply tube
10 a base
21 an ultrasonic homogenizer
22 an ultrasonic transducer
23 an ultrasonic oscillator
24 an ultrasonic horn
31 a homogenous valve
32 a valve seat
33 a valve rod
34 a breaker ring
35 an entrance
36 a gap
37 an exit

What is claimed is:

1. A method of surface treatment comprising:
preparing a raw material solution comprising a chemical substance and a solvent with a boiling point;
homogenizing the raw material solution comprising the chemical substance and the solvent;
generating atomized droplets by atomizing the raw material solution comprising the chemical substance and the solvent;
supplying carrier gas to the atomized droplets to carry the atomized droplets onto a base; and
causing thermal reaction of the atomized droplets adjacent to the base at a temperature that is the boiling point of the solvent or at a higher temperature than the boiling point of the solvent comprised in the raw material solution to apply surface treatment to the base.

2. The method of claim 1, wherein
the chemical substance comprised in the raw material solution is a raw material for the surface treatment of the base.

3. The method of claim 1, wherein
the surface treatment of the base is forming a film on a surface of the base.

4. The method of claim 1, wherein
the chemical substance comprised in the raw material solution comprises an organic chemical compound.

5. The method of claim 1, wherein
the chemical substance comprised in the raw material solution comprises a low molecular compound.

6. The method of claim 1, wherein
the solvent comprised in the raw material solution comprises an organic solvent.

7. The method of claim 1, wherein
the solvent comprised in the raw material solution comprises an aprotic solvent.

8. The method of claim 1, wherein
the homogenizing the raw material solution comprising the chemical substance and the solvent is done by use of an ultrasonic homogenizer.

9. The method of claim 1, wherein
the generating atomized droplets by atomizing the raw material solution is done using ultrasonic vibration.

10. The method of claim 9, wherein
the ultrasonic vibration comprises a frequency that is 0.5 MHz or more.

11. The method of claim 1, wherein
the carrier gas is supplied to the atomized droplets at a flow rate that is in a range of 0.1 L/min to 10 L/min.

12. The method of claim 1, wherein
the causing the thermal reaction of the atomized droplets adjacent to the base is done at the temperature in a range of 120° C. to 350° C.

13. The method of claim 1, wherein
the homogenizing the raw material solution comprising the chemical substance and the solvent is repeated twice or more during mixing the chemical substance in the solvent and/or after the raw material solution is prepared.

14. The method of claim 11, wherein
the carrier gas further comprises a dilution gas.

15. A method of surface treatment comprising:
preparing a raw material solution by mixing a chemical substance in a solvent with a boiling point;
homogenizing the raw material solution comprising the chemical substance and the solvent during mixing the chemical substance in the solvent and/or after the raw material solution is prepared;
generating atomized droplets by atomizing the raw material solution comprising the chemical substance and the solvent;
supplying carrier gas to the atomized droplets to carry the atomized droplets onto a base; and
causing thermal reaction of the atomized droplets adjacent to the base at a temperature that is the boiling point of the solvent or at a higher temperature than the boiling point of the solvent comprised in the raw material solution to apply surface treatment to the base.

16. The method of surface treatment of claim 15, wherein
the chemical substance comprised in the raw material solution comprises an organic chemical compound.

17. The method of claim 15, wherein
the solvent comprised in the raw material solution comprises an aprotic solvent.

18. The method of claim 15, wherein
the homogenizing the raw material solution comprising the chemical substance and the solvent is done by use of an ultrasonic homogenizer.

19. The method of claim 15, wherein
the generating atomized droplets by atomizing the raw material solution is done using ultrasonic vibration.

20. The method of claim 15, wherein
the ultrasonic vibration comprises a frequency that is 0.5 MHz or more.
